(19) United States
(12) Patent Application Publication
(10) Pub. No.: US 2022/0371152 A1
(43) Pub. Date: Nov. 24, 2022

(54) FOURIER FILTERING OF SPECTRAL DATA FOR MEASURING LAYER THICKNESS DURING SUBSTRATE PROCESSING

(71) Applicant: Applied Materials, Inc., Santa Clara, CA (US)

(72) Inventors: Benjamin Cherian, Mountain View, CA (US); Dominic J. Benvegnu, La Honda, CA (US); Harry Q. Lee, Los Altos, CA (US)

(73) Assignee: Applied Materials, Inc., Santa Clara, CA (US)

(21) Appl. No.: 17/325,364

(22) Filed: May 20, 2021

(51) Int. Cl. B24B 37/013; H01L 21/66; H01L 21/321; H03H 17/02

(52) U.S. Cl. CPC B24B 37/013; H01L 22/26; H01L 21/3212; H03H 17/0213; H01L 21/7684

(57) ABSTRACT

Determining a thickness of a layer on a wafer during a semiconductor process may include executing the process on the layer on the wafer; monitoring the wafer during the process with an in-situ spectrographic monitoring system to generate spectral data reflected from the wafer; applying a bandpass filter operation to the spectral data to generate filtered spectral data, where the bandpass filter may be configured to pass a frequency range corresponding to the layer on the wafer; and matching the filtered spectral data to a reference filtered spectral data, where the reference filtered spectral data may have been filtered using the bandpass filter operation, and the reference filtered spectral data may be associated with a thickness of the layer.

### TECHNICAL FIELD

This disclosure generally relates to monitoring optical spectral data during processing of semiconductor substrates. Specifically, this disclosure describes Fourier filtering of spectral data to measure a layer thickness during a substrate process.

### BACKGROUND

An integrated circuit is typically formed on a substrate by the sequential deposition of conductive, semiconductive, and/or insulative layers on a silicon wafer. A variety of fabrication processes use the planarization of a layer on the substrate between processing steps. For example, for certain applications, e.g., polishing of a metal layer to form vias, plugs, and/or lines in the trenches of a patterned layer, an overlying layer is planarized until the top surface of a patterned layer is exposed. In other applications, e.g., planarization of a dielectric layer for photolithography, an overlying layer is polished until a desired thickness remains over the underlying layer.

Chemical mechanical polishing (CMP) is one common method of planarization. This planarization method typically requires that the substrate be mounted on a carrier or polishing head. The exposed surface of the substrate is typically placed against a rotating polishing pad. The carrier head provides a controllable load on the substrate to push it against the polishing pad. Abrasive polishing slurry is typically supplied to the surface of the polishing pad.

One problem in CMP is determining whether the polishing process is complete, i.e., whether a substrate layer has been planarized to a desired flatness or thickness, or when a desired amount of material has been removed. Variations in the slurry distribution, the polishing pad condition, the relative speed between the polishing pad and the substrate, and/or the load on the substrate can cause variations in the material removal rate. These variations, as well as variations in the initial thickness of the substrate layer, cause variations in the time needed to reach the polishing endpoint. Therefore, determining the polishing endpoint merely as a function of polishing time can lead to within-wafer non-uniformity (WTWNU) and wafer-to-wafer non-uniformity (WTWNU).

In some systems, a substrate is optically monitored in-situ during polishing, e.g., through a window in the polishing pad. However, existing optical monitoring techniques may not satisfy increasing demands of semiconductor device manufacturers.

### SUMMARY

In some embodiments, a method of determining a thickness of a layer on a wafer during a chemical-mechanical polishing (CMP) process may include polishing the layer on the wafer using the CMP process; monitoring the wafer during the CMP process with an in-situ spectrographic monitoring system to generate spectral data reflected from the wafer; applying a bandpass filter operation to the spectral data to generate filtered spectral data, where the bandpass filter may be configured to pass a frequency range corresponding to the layer on the wafer; and matching the filtered spectral data to a reference filtered spectral data, where the reference filtered spectral data may have been filtered using the bandpass filter operation, and the reference filtered spectral data may be associated with a thickness of the layer.

In some embodiments, a system may include a polishing pad; a carrier head configured to hold a wafer against the polishing pad; a monitoring system configured to direct light onto the wafer and receive light reflected from the wafer; one or more processors; and one or more memory devices. The one or more memory devices may include instructions that, when executed by the one or more processors, cause the one or more processors to perform operations including: receiving spectral data based on the light reflected from the wafer; applying a bandpass filter operation to the spectral data to generate filtered spectral data, where the bandpass filter may be configured to pass a frequency range corresponding to a layer on the wafer; matching the filtered spectral data to a reference filtered spectral data, where the reference filtered spectral data may have been filtered using the bandpass filter operation, and the reference filtered spectral data may be associated with a thickness of the layer; and controlling a polishing process of the wafer based on the thickness.

In some embodiments, a non-transitory computer-readable medium may include instructions that, when executed by one or more processors, cause the one or more processors to perform operations including receiving spectral data based on light reflected from a wafer; applying a bandpass filter operation to the spectral data to generate filtered spectral data, where the bandpass filter may be configured to pass a frequency range corresponding to a layer on the wafer; matching the filtered spectral data to a reference filtered spectral data, where the reference filtered spectral data may have been filtered using the bandpass filter operation, and the reference filtered spectral data may be associated with a thickness of the layer; and controlling a process performed on the wafer based on the thickness.

In any embodiments, any and all of the following features may be implemented in any combination and without limitation. The method/operations may also include generating a plurality of reference filtered spectral data by simulating a model corresponding to the wafer. Matching the filtered spectral data to the reference filtered spectral data may include calculating a similarity between the filtered spectral data and each of the plurality of reference filtered spectral data to identify the reference filtered spectral data as the most similar to the filtered spectral data. The model corresponding to the wafer may include a simplified model that removes patterned features and/or layers below the layer on the wafer. The bandpass filter operation may remove frequency components from spectral data that are associated with the patterned features and/or the layers below the layer on the wafer. The reference filtered spectral data may be derived from spectral data measurements and thickness measurements from a setup wafer. The method/operations may also include operating the CMP process based on the thickness of the layer until the layer on the wafer reaches a target thickness. The method/operations may also include converting the spectral data into wavenumber space to generate wavenumber data representing a number of in-layer waves in the layer, where the wavenumber space may depend on a wavelength-dependent refractive index of the layer for each data point in the spectral data. The method/operations may also include interpolating the wavenumber data onto an evenly spaced distribution of wavenumber values. The evenly spaced distribution of wavenumber values may include a power-of-2 number of wavenumber values. The method/operations may also include calculating a Discrete Fourier Transformer (DFT) of the wavenumber data to generate DFT data, and/or identifying a window in the DFT data corresponding to an estimated thickness of the layer. Applying the bandpass filter operation may include setting values in the DFT data outside of the window to zero. The spectral data may include a plurality of peaks that may be associated with layers other than the layer on the wafer. The method/operations may also include identifying a frequency corresponding to a peak associated with the layer; and applying the bandpass filter operation to the spectral data in a wavenumber domain or a wavelength domain, where the bandpass filter operation may be centered on the frequency corresponding to the peak.

### BRIEF DESCRIPTION OF THE DRAWINGS

A further understanding of the nature and advantages of various embodiments may be realized by reference to the remaining portions of the specification and the drawings, wherein like reference numerals are used throughout the several drawings to refer to similar components. In some instances, a sub-label is associated with a reference numeral to denote one of multiple similar components. When reference is made to a reference numeral without specification to an existing sub-label, it is intended to refer to all such multiple similar components.

FIG. 1 illustrates a schematic cross-sectional view of an example of a polishing apparatus, according to some embodiments.

FIG. 2 illustrates a measured spectrum from the in-situ optical monitoring system, according to some embodiments.

FIG. 3 illustrates a path of a sequence of spectral measurements on the substrate, according to some embodiments.

FIG. 4 illustrates light reflections that may be measured from a wafer, according to some embodiments.

FIG. 5 illustrates a flowchart of a method for determining a thickness of the layer on a wafer during a CMP process.

FIG. 6 illustrates a flowchart of a method for applying a bandpass filter operation, according to some embodiments.

FIG. 7 illustrates a graph of spectral data that may be received from a spectrometer, according to some embodiments.

FIG. 8 illustrates a graph of the spectral data after being translated to an evenly spaced wavenumber space, according to some embodiments.

FIG. 9 illustrates a graph of the DFT of the spectral wavenumber data, according to some embodiments.

FIG. 10 illustrates a graph of the intensity of the filtered spectral data in wavenumber space after calculating the inverse DFT, according to some embodiments.

FIG. 11 illustrates an exemplary computer system, in which various embodiments may be implemented.

### DETAILED DESCRIPTION

This disclosure describes methods and systems for using a Fourier analysis to locate and apply a bandpass filter to spectral data when measuring thickness of a layer on a wafer. During a semiconductor process, the thickness of a top layer of the wafer may be continuously measured until it reaches a target thickness. For example, a polishing process may remove material from a top layer until the target thickness is reached. The real-time thickness of the layer is measured by directing light onto layer and measuring the reflected spectral data using a spectrometer. The spectral data may then be correlated with a set of reference spectral data having a known thickness to estimate the current thickness of the layer. However, models used to generate the set of reference spectral data must be very high-fidelity to result in an accurate match, and finding peaks in a Fourier analysis that correspond to the layer amongst all of the reflected wavelengths has a limited resolution, thus making accurate thickness measurements very difficult.

These embodiments improve the accuracy of measuring a layer thickness using spectral data. The spectral data may be converted into wavenumber space and interpolated onto an evenly spaced distribution. A Discrete Fourier Transform (DFT) may be calculated for the wave number data, and an estimated or known location of a peak may be identified in the Fourier space. Once this location is identified, a bandpass filter can be applied by zeroing DFT values in the Fourier space, or the bandpass filter may be otherwise applied in the wavenumber or wavelength space. The inverse DFT may be calculated, and the resulting spectral data may then primarily represent the layer being measured, as wavelength components resulting from patterned features and/or underlying layers have been removed. This process may be carried out for the reference data using a simplified wafer model and for in-situ live measurements to ensure an accurate match.

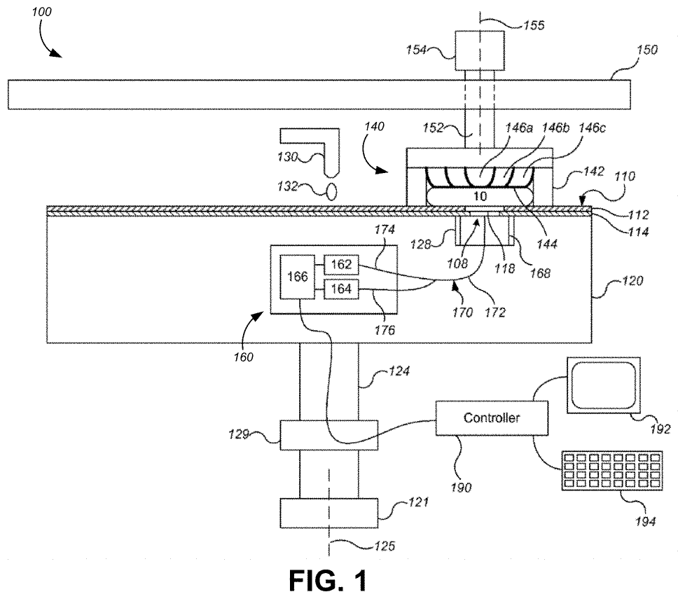

FIG. 1 illustrates an example of a polishing apparatus 100. The polishing apparatus 100 may include a rotatable disk-shaped platen 120 on which a polishing pad 110 may be situated. The platen may be operable to rotate about an axis 125. For example, a motor 121 may turn a drive shaft 124 to rotate the platen 120. The polishing pad 110 may be a two-layer polishing pad with an outer polishing layer 112 and a softer backing layer 114.

The polishing apparatus 100 may include a port 130 to dispense polishing liquid 132, such as slurry, onto the polishing pad 110. The polishing apparatus may also include a polishing pad conditioner to abrade the polishing pad 110 to maintain the polishing pad 110 in a consistent abrasive state.

The polishing apparatus 100 may include at least one carrier head 140. The carrier head 140 may be operable to hold a substrate 10 against the polishing pad 110. The carrier head 140 may have independent control of the polishing parameters, for example pressure, associated with each respective substrate.

In particular, the carrier head 140 may include a retaining ring 142 to retain the substrate 10 below a flexible membrane 144. The carrier head 140 may also include a plurality of independently controllable pressurizable chambers defined by the membrane, e.g., three chambers 146a-146c, which may apply independently controllable pressures to associated zones on the flexible membrane 144 and thus on the substrate 10. Although only three chambers are illustrated in FIG. 1 for ease of illustration, there could be one or two chambers, or four or more chambers, e.g., five chambers in other embodiments.

The carrier head 140 may be suspended from a support structure 150, e.g., a carousel or a track, and may be connected by a drive shaft 152 to a carrier head rotation motor 154 so that the carrier head can rotate about an axis 155. Optionally the carrier head 140 may oscillate laterally, e.g., on sliders on the carousel 150 or track; or by rotational oscillation of the carousel itself. In operation, the platen may be rotated about its central axis 125, and the carrier head may be rotated about its central axis 155 and/or translated laterally across the top surface of the polishing pad.

While only one carrier head 140 is shown, more carrier heads may be provided to hold additional substrates so that the surface area of polishing pad 110 may be used efficiently.

The polishing apparatus may also include an in-situ monitoring system 160. The in-situ monitoring system may generate a time-varying sequence of values that depend on the thickness of a layer on the substrate. The in-situ-monitoring system 160 may include an optical monitoring system. In particular, the in-situ-monitoring system 160 may measure a sequence of spectra of light reflected from a substrate during polishing.

An optical access 108 through the polishing pad may be provided by including an aperture (i.e., a hole that runs through the pad) or a solid window 118. The solid window 118 may be secured to the polishing pad 110, e.g., as a plug that fills an aperture in the polishing pad. The solid window may alternatively be molded to or adhesively secured to the polishing pad, although in some implementations the solid window can be supported on the platen 120 and project into an aperture in the polishing pad.

The optical monitoring system 160 may include a light source 162, a light detector 164, and circuitry 166 for sending and receiving signals between a remote controller 190, e.g., a computer, and the light source 162 and light detector 164. One or more optical fibers can be used to transmit the light from the light source 162 to the optical access in the polishing pad, and to transmit light reflected from the substrate 10 to the detector 164. For example, a bifurcated optical fiber 170 may be used to transmit the light from the light source 162 to the substrate 10 and back to the detector 164. The bifurcated optical fiber may include a trunk 172 positioned in proximity to the optical access, and two branches 174 and 176 connected to the light source 162 and detector 164, respectively.

In some implementations, the top surface of the platen can include a recess 128 into which is fit an optical head 168 that holds one end of the trunk 172 of the bifurcated fiber. The optical head 168 may include a mechanism to adjust the vertical distance between the top of the trunk 172 and the solid window 118.

The output of the circuitry 166 may be a digital electronic signal that passes through a rotary coupler 129, e.g., a slip ring, in the drive shaft 124 to the controller 190 for the optical monitoring system. Similarly, the light source may be turned on or off in response to control commands in digital electronic signals that pass from the controller 190 through the rotary coupler 129 to the optical monitoring system 160. Alternatively, the circuitry 166 may communicate with the controller 190 by a wireless signal.

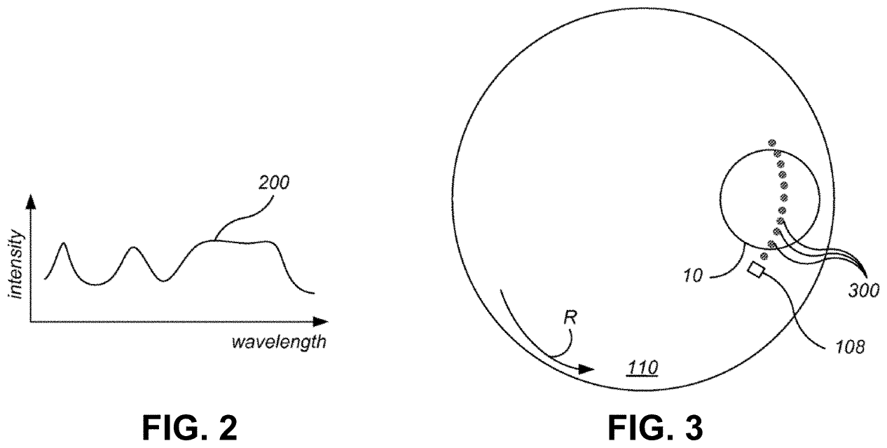

The light source 162 may be operable to emit ultraviolet (UV), visible light, or near-infrared (NIR) light. The light detector 164 may be a spectrometer. A spectrometer is an optical instrument for measuring intensity of light over a portion of the electromagnetic spectrum. For example, a grating spectrometer may be used. Typical outputs for a spectrometer may include the intensity of the light as a function of wavelength (or frequency). FIG. 2 illustrates an example of a measured spectrum 200 with intensity as a function of wavelength.

As noted above, the light source 162 and light detector 164 may be connected to a computing device, e.g., the controller 190, operable to control their operation and receive their signals. The computing device may include a microprocessor situated near the polishing apparatus. For example, the computing device may be a programmable computer. With respect to control, the computing device may, for example, synchronize activation of the light source with the rotation of the platen 120. A display 192, e.g., an LED screen, and a user input device 194, e.g., a keyboard and/or a mouse, may be connected to the controller 190.

In operation, the controller 190 may receive, for example, a signal that carries information describing a spectrum of the light received by the light detector for a particular flash of the light source or time frame of the detector. Thus, this spectrum may be a spectrum measured in-situ during polishing. Without being limited to any particular theory, the spectrum of light reflected from the substrate 10 may evolve as polishing progresses due to changes in the thickness of the outermost layer, thus yielding a sequence of time-varying spectra.

The optical monitoring system 160 may be configured to generate a sequence of measured spectra at a measurement frequency, or “spectral data.” The relative motion between the substrate 10 and the optical access 108 causes spectra in the sequence to be measured at different positions on the substrate 10. In some implementations, the light beam generated by the light source 162 may emerge from a point that rotates (shown by arrow R in FIG. 3) with the platen 120. As shown in FIG. 3, in such an implementation, the relative motion between the substrate 10 and the optical access 108 can cause spectra to be measured at positions 300 in a path across the substrate 10. In some implementations only one spectrum is measured per rotation of the platen. In addition, in some implementations, the emitting point of the light beam is stationary and measurements are taken only when the optical access 108 aligns with the light beam.

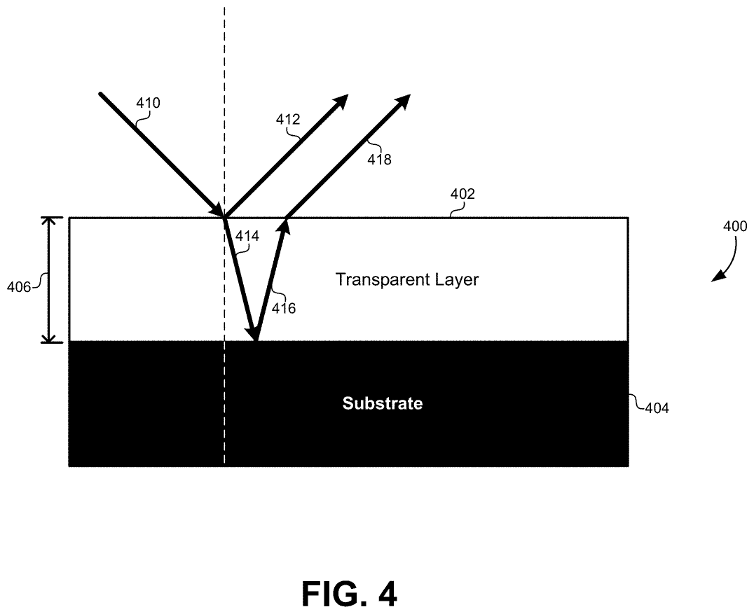

FIG. 4 illustrates light reflections that may be measured from a wafer 400, according to some embodiments. Note that this represents a simplified representation of the wafer 400 that includes a substrate 404 and a transparent layer 402. In practice, the wafer 400 may include many additional layers in addition to the substrate 404 and the transparent layer 402. Additionally, the various layers may include complex patterned structures, including traces, vias, and/or other elements of integrated circuits that have been omitted from FIG. 4 for the sake of clarity.

In this example, the transparent layer 406 may be placed against the polishing pad of a CMP system in order to incrementally remove a portion of the transparent layer 402 until a target thickness for the transparent layer 402 has been reached. In order to monitor the current thickness 406 of the transparent layer 402, the optical monitoring system may include a spectrographic monitoring system as described above that directs light 410 at the transparent layer 402 and measures any resulting reflections at a spectrometer. As described below, a technique has been developed to accurately determine a thickness 406 of the transparent layer 402 using the measured resulting reflections. Measurements of the thickness 406 may be made continuously during the polishing process such that the polishing process may be terminated when the thickness 406 of the transparent layer 402 reaches the target thickness.

Determining the thickness 406 may use the reflectance measurements of various wavelengths that are captured by the spectrographic monitoring system. Light reflected back by the various layers and/or features in the wafer 400 may be collected by a spectrometer where these measurements may be spectrally resolved. The computer may store these measurements as spectral data. As illustrated in FIG. 4, the spectral data may include an initial reflection 412 incident off the transparent layer 402. The spectral data may also include one or more reflections that are incident off the boundaries between additional layers in the wafer 400 or off of features in the layers of the wafer 400. In the simplified example of FIG. 4, this may include light 414 that passes through the transparent layer 402 and is returned as a reflection 416 off the boundary between the transparent layer 402 and the substrate 404. This reflection 416 may then pass back out of the transparent layer 402 and be received as a reflection 418 by the spectrometer. Although not shown explicitly in FIG. 4, additional reflections recorded by the spectrometer may include reflections off of additional layer boundaries and other patterned structures in the various layers that may be present in the wafer 400.

A number of different techniques have been proposed to measure the current thickness 406 of the transparent layer 402 using the spectral data. One method may use the reflectance versus wavelength information in the spectral data to perform a Fourier analysis on the spectral data. For example, the spectral data may be converted into the Fourier domain using a Discrete Fourier Transform (DFT). The resulting frequency distribution may be analyzed to locate a peak that is associated with the transparent layer 402. The location of this peak can then be correlated with a number representing the thickness 406 of the transparent layer 402. However, this technique has a limited resolution, and therefore may be problematic when precise thickness measurements are needed.

Another method for measuring the thickness 406 of the transparent layer 402 involves using simulations of the layer stack on the wafer 400. An accurate model of the various layers and patterned features in the wafer 400 may be developed, and the light reflections may be simulated at each incremental thickness of the transparent layer 402. The resulting simulated spectral data sets may then be stored along with the corresponding thickness used in each simulation. When an actual measurement of spectral data is received from the spectrometer, a closest match in the simulated spectral data may be identified for the measured spectral data. The thickness of the transparent layer used in the matching simulated spectral data may then be used as the approximate thickness 406 of the transparent layer 402 at that point in the polishing process. However, for this method to be accurate, the model of the wafer must be accurate and represent all of the various layers and patterned features in the actual wafer 400. Not only does this complicate the model, but the patterns and circuit layouts in the wafer 400 may change with every batch of wafers polished by the CMP machine. Thus it is difficult to generate models that accurately represent all of the various layers that may be present in a wafer, which in turn complicates the process of matching the measured spectral data to the right corresponding simulated spectral data to determine an accurate thickness.

The embodiments described herein solve these and other technical problems for measuring the thickness of a top layer on a wafer during various semiconductor processes. Specifically, the spectral data may be filtered in order to focus on the layer being polished. A bandpass filter may be applied to remove frequency components in the spectral data that are associated with layers and features that are not related to the top layer being polished. This bandpass filtering operation may be applied to in-situ measurements that are received during the polishing process, as well as to simulated spectral data that may be used as a reference. Because the frequency components resulting from other layers/features in the wafer are removed using the bandpass filter from both the in-situ measurements and the simulated spectral data, a simplified model may be used for simulations that can largely ignore the complex patterns and features that may change with every wafer. The filtered measured spectral data can then be compared to filtered simulated results from the simplified model to identify an approximate thickness that is much more accurate than previous techniques that relied on complex wafer models. For example, a DFT may be performed on the spectral data after being converted to wavenumber space. The bandpass filtering operation may then zero out frequency components that are not associated with an approximate expected thickness of the film of interest in the wafer. The inverse DFT can convert the data back to wavenumber space, after which any of the existing techniques can be used to determine a thickness of the top layer.

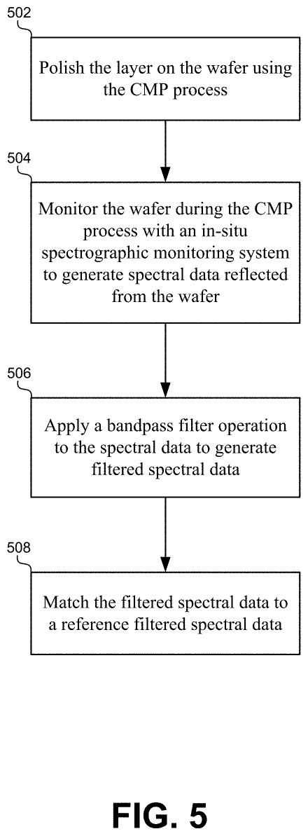

FIG. 5 illustrates a flowchart 500 of a method for determining a thickness of the layer on a wafer during a CMP process. The method may include polishing the layer on the wafer using a CMP process (502). This method may be performed by the various components of the polishing apparatus 100 described above and illustrated in FIG. 1. The method may also include monitoring the wafer during the CMP process with an in-situ spectrographic monitoring system to generate spectral data reflected from the wafer (504). As described above, this may include causing light to be directed at the wafer and receiving reflected wavelengths that are measured by a spectrometer. The spectrometer may be controlled by a computer system. Therefore, some steps in this method may be executed by one or more processors as a result of instructions stored on a non-transitory, computer-readable medium. The spectral data may be stored and/or processed by the computer system.

The method may additionally include applying a bandpass filter operation to the spectral data to generate filtered spectral data (506). For example, some embodiments may change the spectral data to a wavenumber space, interpolate the wavenumber space data to a regularly-spaced set of points, and execute a DFT to generate spectral frequency data in the Fourier domain. A peak corresponding to the approximate layer thickness may be identified in the Fourier domain, and the bandpass filter operation may set values outside of a window around the peak to zero in the Fourier domain. The inverse of the filtered frequency data may then be transformed back into the wavenumber space and/or back into the spectral data format. This process is described in greater detail below throughout the remainder of this disclosure.

The process of applying the bandpass filter operation may be executed in a number of different ways. For example, instead of applying a hard bandpass filter in the form of a threshold window in the Fourier domain, some embodiments may instead multiply the DFT with a smoothing window function (e.g., a Hann window, a Blackman window, etc.). Alternatively, some embodiments may simply use the DFT to identify a central location for the bandpass frequency window and instead apply a standard bandpass filter in the wavenumber domain. As described below, these techniques may be used to identify where to center the bandpass filter, but the type of bandpass filter and where that bandpass filter is executed are not limited by this disclosure. Instead, any type of filter may be used, and the filter may be applied at any point in the process after the location of the filter is known. Therefore, the specific method of executing the bandpass filter operation described below is provided only by way of example and is not meant to be limiting.

The method may further include matching the filtered spectral data to a reference filtered spectral data (508). The process described above may be used to filter both real-world measurements that happen in-situ as well as simulated data generated from a model of a wafer being polished. For example, the spectral data may be read from real-time measurements taken by the CMP machine during a live polishing process. Alternatively, the spectral data may be generated from a simulation using a model that closely approximates the wafer being polished. In order to determine a wafer thickness using the real-time measurements, the filtered spectral data may be matched with a set of reference filtered spectral data from a simulation. Once this match is made, the known layer thickness that was used for the simulation may also be assigned to the layer on the wafer being processed as a current thickness measurement. The current thickness measurement may then be used to control the operation of the CMP machine such that it polishes the layer until the current thickness measurement reaches the target thickness measurement.

Typically, making this match between spectral data and reference spectral data is difficult for the reasons described above. Namely, the model must be very high fidelity, and most closely match the actual physical characteristics of the wafer being processed. Otherwise the reflected spectral data in the in-situ measurement will be different from the simulated spectral data made available as a reference from the model. However, by applying the bandpass filter operation described herein, the model can be greatly simplified. Because the bandpass filter attenuates or removes the frequency components that are not attributable to the top layer being polished, the other reflections that occur in the in-situ measurements are removed. Because the same filtering operation is applied to the simulated data, the filtered spectral data from the simplified model will tend to match the filtered spectral data from the measurements much more accurately than if the bandpass filter was not applied.

A simplified model may use a “blanket-film” representation of the actual film stack in the wafer. This may be contrasted with a “complex” model which attempts to calculate diffractive effects from the patterning in each of the various layers on the wafer. Layers with complex pattern structures may be replaced by non-physical blanket layers that represent an effective index of refraction. Other layers or features may safely be ignored if they have only a minimal effect on the spectral data. For example, a layer of silicon, followed by N layers of patterned Cu interconnects, followed by a glue layer, followed by another silicon layer may be model in the simplified model as a silicon/glue/silicon set of layers. This allows the simple model to cover a wider range of different circuit designs and patterns that may be implemented on a particular wafer.

It should be appreciated that the specific steps illustrated in FIG. 5 provide particular methods of measuring a thickness of a wafer being processed, according to various embodiments. Other sequences of steps may also be performed according to alternative embodiments. For example, alternative embodiments may perform the steps outlined above in a different order. Moreover, the individual steps illustrated in FIG. 5 may include multiple sub-steps that may be performed in various sequences as appropriate to the individual step. Furthermore, additional steps may be added or removed depending on the particular applications. Many variations, modifications, and alternatives also fall within the scope of this disclosure.

Although the CMP process described above and depicted in FIG. 1 is used as an example in this disclosure as a practical application of these measurement techniques, the CMP process is provided only by way of example and is not meant to be limiting. The same techniques using reflected light and a spectrometer may be used in measure the thickness of any type of semiconductor layer during any type of manufacturing process. For example, layer thickness may be measured during a deposition process or during processes where films are grown on a wafer. Layer thicknesses may also be measured using these techniques when material is being etched or otherwise removed from the wafer. Some embodiments may also use these techniques to measure layer thickness to test or characterize a manufacturing process or to verify that a wafer was manufactured correctly. Therefore, the CMP process and machinery used as an enabling example may be replaced with other types of machinery and/or processes without restriction as within the scope of this disclosure.

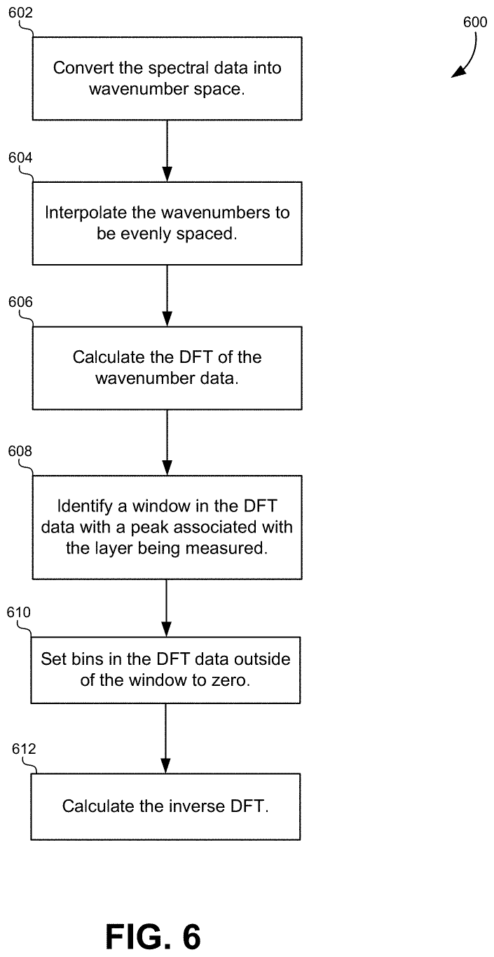

FIG. 6 illustrates a flowchart 600 of a method for applying a bandpass filter operation, according to some embodiments. Flowchart 600 may represent one method of applying the bandpass filter operation described above in flowchart 500. This method may be executed by a computer or computer system comprising one or more processors. The computer system may also include one or more memory devices storing instructions that, when executed by the one or more processors, cause the one or more processors to perform these operations.

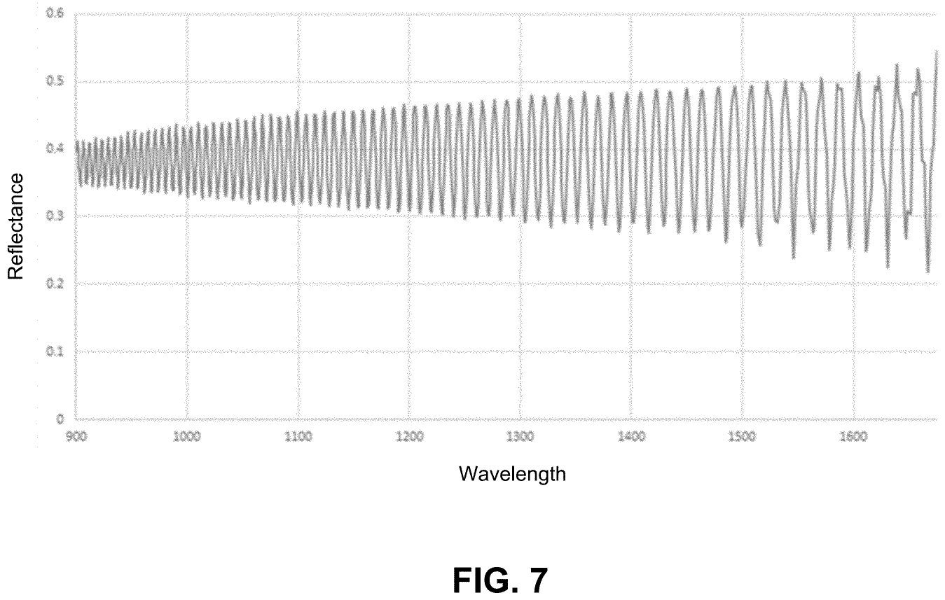

The method may include converting the spectral data into wavenumber space (602). The computer system may receive the spectral data from the spectrometer. The original data from the spectrometer may include counts from a detector of light wavelengths that are received over a time interval. Therefore, the spectral data may include a spectrum of counts at each wavelength. FIG. 7 illustrates a graph of spectral data that may be received from a spectrometer. In this example, the monitored wavelengths may be between 900 nm and 1675 nm, although other ranges of wavelengths may be monitored and/or processed in other embodiments. Note that some embodiments may use a referencing process that uses reflections from a bare silicon wafer for which the reflection properties are known and which is easily simulated. The in situ data being measured can be compared to the reference data to generate a referenced spectrum, which may be proportional to the reflectance versus the wavelength.

To convert the spectral data into wavenumber space instead of wavelength space, each wavelength would be replaced by the index of refraction at that wavelength divided by the wavelength. Although typical wavenumbers are calculated without respect to the index of refraction, these embodiments include the wavelength-dependent index of refraction in the numerator to account for the dispersal of the layer being measured. This allows the wavenumber to represent how many wavelengths fit inside of the layer. Because it is wavelength-dependent, the index of refraction is a measure of how the wave is compressed inside the layer. For example, if n=2 at a particular wavelength inside of the layer, the effective wavelength inside the layer will be half of what it would be in a vacuum. By including the index of refraction, this process more accurately reflects the true wavenumber inside the layer. Note that the conversion to wavenumber space does not change the values of the spectral data on the Y-axis, rather it simply changes the units on the X-axis. The data may now represent intensity versus wavenumber rather than intensity versus wavelength.

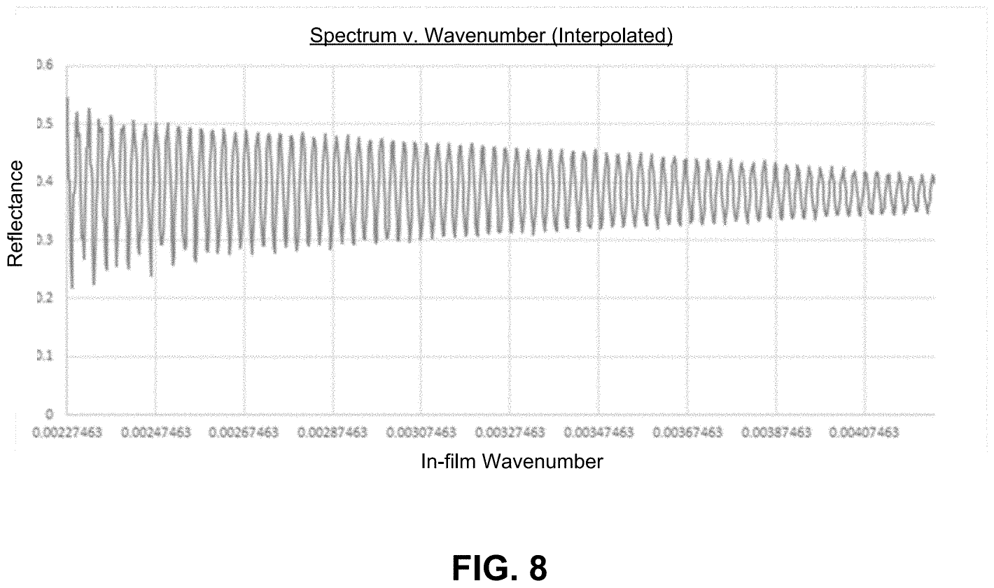

The method in FIG. 6 may also include interpolating the wavenumber to be evenly spaced (604). The wavelength data from the spectrometer will typically be evenly spaced (e.g., data every nanometer). However, since the evenly spaced wavelengths are in the denominator of the wavenumber calculation, the resulting data points in wavenumber space will not be evenly spaced. This can be problematic for efficiently performing a DFT using the Fast Fourier Transform (FFT) algorithm. Therefore, some embodiments may interpolate the unevenly spaced values in wavenumber space to a set of evenly spaced distribution of wavenumber values. In order to use the FFT algorithm, the “grid” to which the unevenly spaced wavenumbers will be interpolated may use a power-of-2 number of points. For example, for the wavelengths of 900 nm to 1675 nm in the spectral data described above, this may correspond to 1024 points in the interpolated wavenumber space. For example, the first wavenumber point[0] can be interpolated to be 3.81/1675=0.00227463 and the last wavenumber point[1023] can be interpolated to be 3.81/900=0.004233, with the wavenumber points in between being linearly interpolated between these two points. FIG. 8 illustrates a graph of the spectral data after being translated to an evenly spaced wavenumber space, according to some embodiments.

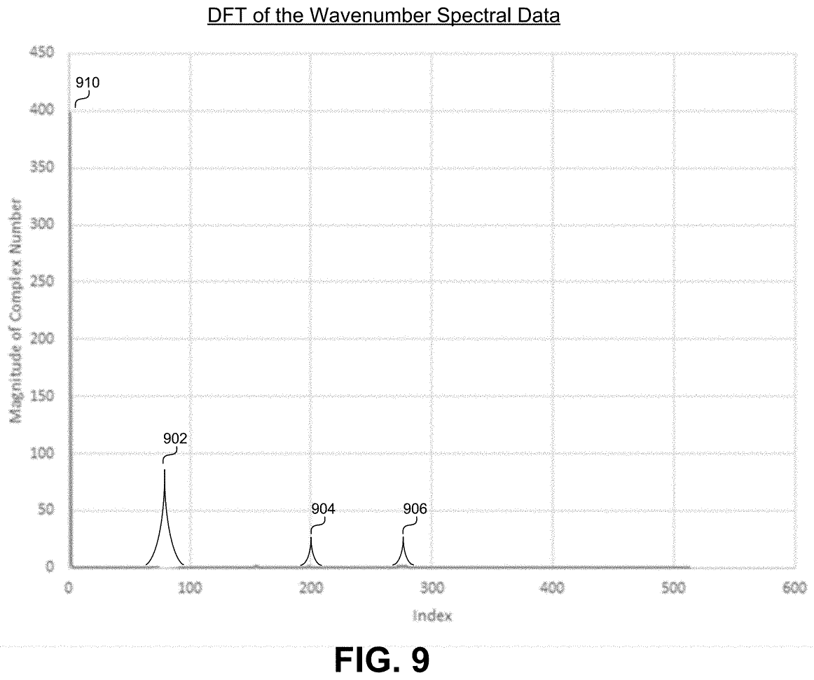

The method of FIG. 6 may additionally include calculating a DFT of the wavenumber spectral data (606). FIG. 9 illustrates a graph of the DFT of the spectral wavenumber data. The DFT represents the wavenumber spectral data after it has been transformed into the Fourier space. As with traditional time-based data, the DFT represents the spectrum as a sum of sines and cosines. However, the frequencies refer to the spacing along the wavenumber axis rather than the frequency of the reflected light. The Y-axis in FIG. 9 represents the magnitude coefficient associated with the sum of the signs and cosines, and the X-axis represents the index in the DFT data. Bin[0] includes a peak 910 that represents the DC offset of the system. Each successive bin may represent the coefficient for the term having the frequency of Bin[n]/signal_length, where the signal_length in this example is 1024. Note that the maximum representable frequency for a signal captured using a sampling frequency of K is K/2, which in this example corresponds to 512/signal_length, or (512/1024) (1/signal_spacing), which equals 0.5*sampling_frequency.

The method may further include identifying a window in the DFT data with a peak associated with the layer being measured (608). The peak 910 associated with the DC offset may be disregarded in most cases. Additionally, the DFT data may include a one or more additional peaks. These peaks may include a peak 902 associated with the current layer being polished. Additional peaks, such as peak 904 and peak 906 may be associated with other internal layers or pattern features in the wafer. At this stage, the approximate bin where the peak associated with the can be determined. For example, when working with simulated data from the simple model described above, the thickness of the layer will already be known from the simulation. The approximate bin for the peak 902 associated with the layer can be determined by multiplying the thickness from the simulation by 2, then multiplying by the difference between the difference upper and lower bounds of the in-film wavenumber over which the data is interpolated. The result may then be rounded to an integer value indicating an approximate bin of the center of the peak 902.

After identifying the center bin for the peak 902, a window in the DFT data can be determined that is centered around the center bin. For example, to capture the peak 902, one half of the window size may be added to and/or subtracted from the center bin location to generate upper and lower bounds for the window. For example, the lower bound may be determined by subtracting 5000 μm from the center bin location, and the upper bound may be determined by adding 5000 μm to the center bin location. These thickness distances may be converted into DFT bin numbers to identify upper and lower bins that define the window around the peak 902.

Note that identifying the window around the peak 902 may be performed without first identifying the location of the peak 902 in the DFT data. Instead, the window around the peak 902 may be identified using the known thickness of the data from the simulation. At this stage, some embodiments may then locate the peak 902 by centering the search within the window. Because the DFT data may include a number of peaks, such as peak 904 and peak 906 that are not attributable to the layer being measured, identifying the specific peak related to this measure may be complicated using conventional techniques. However, by first identifying the window and limiting the search to the area within the window, the peak 902 associated with the layer being measured can be easily distinguished from the other peaks in the DFT data.

The method may also include setting bins in the DFT data outside of the window to zero (610). Setting these values to zero acts as a bandpass filter on the data to remove the peaks that are not associated with the layer being measured. As described above, performing this bandpass filter operation on the DFT data using the window around the peak 902 is just one example of how this bandpass filter operation may be implemented. Once the location of the peak 902 is calculated or known from the simulation data, this bandpass filter operation may be performed at different times during the execution of this method. For example, a corresponding filter may be centered on the peak in the wavenumber space or the wavelength space. However, performing the bandpass filter operation on the DFT data is computationally simplified by simply setting the bin values to zero without requiring additional calculations or mathematical operations.

Optionally, some embodiments may normalize the DFT data using the height of the peak 902 associated with the layer being measured. This can be useful in cases where the sinusoid associated with the layer being measured is damped or muted for reasons that are not easily modeled during simulation. This may cause the measured data to not be easily matched with the simulated data. Therefore, normalizing the DFT data (e.g., dividing the values in the DFT data by the height of the peak 902) may cause the simulated theoretical spectrum and the empirically measured spectrum to have the same heights, and thus ensures that the measured data more closely matches the reference data when determining layer thickness.

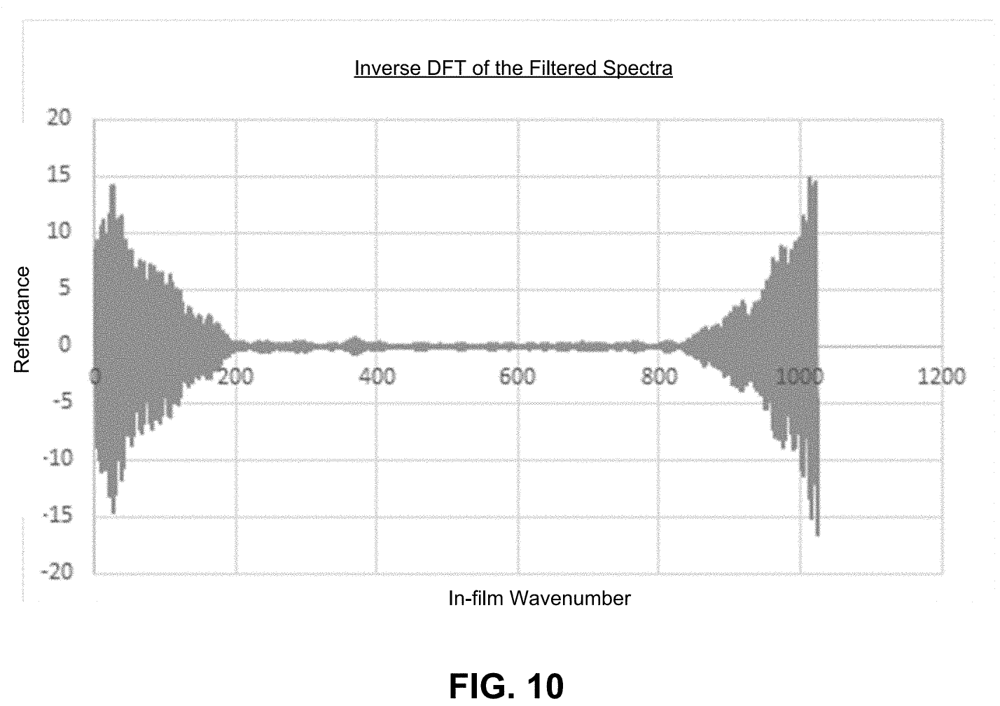

The method may additionally include calculating an inverse DFT of the filtered DFT data to generate filtered wavenumber data (612). This returns the data back to the wavenumber space from the Fourier space. FIG. 10 illustrates a graph of the intensity of the filtered spectral data in wavenumber space after calculating the inverse DFT, according to some embodiments. The filtered spectral data in the wavenumber space represents a wavenumber spectrum that has removed any signal components that are not associated with the film being measured. In effect, this “filters” spectral components for layers that are underneath the top film being measured.

The method depicted in FIG. 6 may be executed a number of different times using simulated spectral data in order to generate a library of reference filtered spectral data for each incremental thickness of the film being measured. This resolution of the incremental thicknesses may be determined by the computational limitations of the simulating computer system or other factors. For example, a range of thicknesses may be divided into a predetermined number of thickness measurements. In some embodiments, the number of different thickness measurements to be simulated may depend on the observable effects of the measurements. In other words, the incremental thicknesses may be based on differences in the thickness at which a significant enough change in the resulting spectral data may be observed.

In addition to generating reference filtered spectral data based on simulated results, the method of flowchart 600 may also be executed for the measured spectral data from a live polishing process. These steps may be executed in substantially the same way as described above for the simulated data to generate filtered spectral data that has the same bandpass filter applied as described above for the simulated data. Thus, the method may be carried out as measurements are received in-situ during a waiver process and compared with reference filtered spectral data to derive live thickness measurements as the wafer is processed.

One difference from the way the method of flowchart 600 may be executed for measured spectral data includes how the location of the peak corresponding to the layer being measured is located in the DFT data. Recall that the bandpass filter can be applied at the location of this peak. When processing simulated spectral data, the location of the peak can be known from the simulation itself. In other words, the simulated thickness of the top layer may be used to identify a location in the DFT and thereby identify a central frequency for the bandpass filter. However, when processing measured spectral data, the actual thickness of the measured data is not known beforehand.

Since the exact thickness is not known when using measured data, some embodiments may instead provide an initial guess about the thickness of the layer at the beginning of the process. After the initial guess is provided, the system can continuously extrapolate future values of the thickness as the process proceeds to each subsequent measurement. For example, some embodiments may use a nominal thickness of the wafer during the polish. This nominal thickness may be provided by a user at the start of the polish. Alternatively, other methods of measuring the thickness of the wafer may be used to automatically determine the thickness of the wafer as a starting point. For example, some processes may expect the thickness to be approximately 70 μm with an error of approximately 5 μm. As the process proceeds, the rate at which material is added to and/or removed from the wafer may be used to estimate future values, which may be extracted from calculated thickness values during the process. The previous thickness values that were determined using this method may then be used to extrapolate the future guesses of the thickness as a starting point for subsequent measurements.

The estimated value for thickness can be used to locate the peak in the DFT data resulting from the measured spectral data. The process described above may be used to identify the location of a bin in the DFT data by multiplying the estimated thickness by 2, and then multiplying by the difference between the bounds of the DFT data. An initial window in the DFT data may then be determined by adding/subtracting a number of bins corresponding to an error thickness on either side of the central location. This window can then be searched for the highest peak bin in the DFT data window. Because the initial guess for the location of the peak will be fairly accurate, the peak can then be easily located within the window and distinguished from other peaks that may correspond to other layers in the wafer. The bandpass filter operation can then be applied to the measured data in the Fourier space, in the wavenumber space, or otherwise as described above for the simulated data case.

The inverse DFT may then be calculated to generate filtered spectral data for the measurement. This data may stay in the wavenumber space or may be converted back to the wavelength space depending on the format of the data in the reference library. In order to determine the actual thickness of the measured data, the filtered spectral data may then be compared to the reference filtered spectral data in the reference library. Various techniques may be used to identify the closest matching reference. For example, some embodiments may calculate a Sum of Square Differences (SSD) between each reference filtered spectral data in the reference library and the measured filtered spectral data. Other embodiments may use cosine similarity as a similarity measure. Some embodiments may also shift the reference filtered spectral data in the wavelength or wavenumber space prior to calculating the cosine similarity. Once a closest match is found, the thickness used in the simulation that generated the reference filtered spectral data may be used as the current thickness of the layer being measured.

Note that the example above uses simulated data to generate the references to which the measured spectral data can be matched. However, other embodiments may use different sources for the reference filtered spectral data. For example, some embodiments may use a library of available spectral data that may be downloaded from a central source or otherwise provided. Some embodiments may use historical measured spectral data derived from actual measurements of wafers being processed. For example, a similar (“setup”) wafer may be set up on the machine and processed (e.g., polished on a CMP machine), and the thickness and/or spectral data may be measured and stored from this wafer for comparison to future similar wafers that will be processed in a similar manner.

It should be appreciated that the specific steps illustrated in FIG. 6 provide particular methods of applying a bandpass filter operation according to various embodiments. Other sequences of steps may also be performed according to alternative embodiments. For example, alternative embodiments may perform the steps outlined above in a different order. Moreover, the individual steps illustrated in FIG. 6 may include multiple sub-steps that may be performed in various sequences as appropriate to the individual step. Furthermore, additional steps may be added or removed depending on the particular applications. Many variations, modifications, and alternatives also fall within the scope of this disclosure.

Each of the methods described herein may be implemented by a computer system. Each step of these methods may be executed automatically by the computer system, and/or may be provided with inputs/outputs involving a user. For example, a user may provide inputs for each step in a method, and each of these inputs may be in response to a specific output requesting such an input, wherein the output is generated by the computer system. Each input may be received in response to a corresponding requesting output. Furthermore, inputs may be received from a user, from another computer system as a data stream, retrieved from a memory location, retrieved over a network, requested from a web service, and/or the like. Likewise, outputs may be provided to a user, to another computer system as a data stream, saved in a memory location, sent over a network, provided to a web service, and/or the like. In short, each step of the methods described herein may be performed by a computer system, and may involve any number of inputs, outputs, and/or requests to and from the computer system which may or may not involve a user. Those steps not involving a user may be said to be performed automatically by the computer system without human intervention. Therefore, it will be understood in light of this disclosure, that each step of each method described herein may be altered to include an input and output to and from a user, or may be done automatically by a computer system without human intervention where any determinations are made by a processor. Furthermore, some embodiments of each of the methods described herein may be implemented as a set of instructions stored on a tangible, non-transitory storage medium to form a tangible software product.

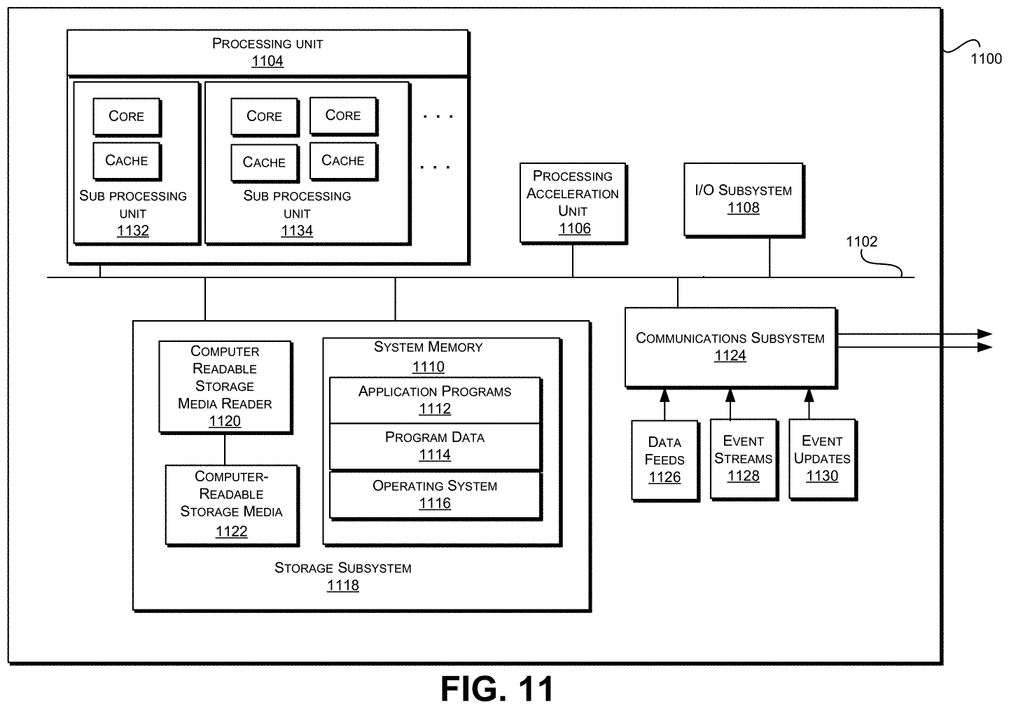

FIG. 11 illustrates an exemplary computer system 1100, in which various embodiments may be implemented. The system 1100 may be used to implement any of the computer systems described above. As shown in the figure, computer system 1100 includes a processing unit 1104 that communicates with a number of peripheral subsystems via a bus subsystem 1102. These peripheral subsystems may include a processing acceleration unit 1106, an I/O subsystem 1108, a storage subsystem 1118 and a communications subsystem 1124. Storage subsystem 1118 includes tangible computer-readable storage media 1122 and a system memory 1110.

Bus subsystem 1102 provides a mechanism for letting the various components and subsystems of computer system 1100 communicate with each other as intended. Although bus subsystem 1102 is shown schematically as a single bus, alternative embodiments of the bus subsystem may utilize multiple buses. Bus subsystem 1102 may be any of several types of bus structures including a memory bus or memory controller, a peripheral bus, and a local bus using any of a variety of bus architectures. For example, such architectures may include an Industry Standard Architecture (ISA) bus, Micro Channel Architecture (MCA) bus, Enhanced ISA (EISA) bus, Video Electronics Standards Association (VESA) local bus, and Peripheral Component Interconnect (PCI) bus, which can be implemented as a Mezzanine bus manufactured to the IEEE P1386.1 standard.

Processing unit 1104, which can be implemented as one or more integrated circuits (e.g., a conventional microprocessor or microcontroller), controls the operation of computer system 1100. One or more processors may be included in processing unit 1104. These processors may include single core or multicore processors. In certain embodiments, processing unit 1104 may be implemented as one or more independent processing units 1132 and/or 1134 with single or multicore processors included in each processing unit. In other embodiments, processing unit 1104 may also be implemented as a quad-core processing unit formed by integrating two dual-core processors into a single chip.

In various embodiments, processing unit 1104 can execute a variety of programs in response to program code and can maintain multiple concurrently executing programs or processes. At any given time, some or all of the program code to be executed can be resident in processor(s) 1104 and/or in storage subsystem 1118. Through suitable programming, processor(s) 1104 can provide various functionalities described above. Computer system 1100 may additionally include a processing acceleration unit 1106, which can include a digital signal processor (DSP), a special-purpose processor, and/or the like.

I/O subsystem 1108 may include user interface input devices and user interface output devices. User interface input devices may include a keyboard, pointing devices such as a mouse or trackball, a touchpad or touch screen incorporated into a display, a scroll wheel, a click wheel, a dial, a button, a switch, a keypad, audio input devices with voice command recognition systems, microphones, and other types of input devices. User interface input devices may include, for example, motion sensing and/or gesture recognition devices such as the Microsoft Kinect® motion sensor that enables users to control and interact with an input device, such as the Microsoft Xbox® 360 game controller, through a natural user interface using gestures and spoken commands. User interface input devices may also include eye gesture recognition devices such as the Google Glass® blink detector that detects eye activity (e.g., ‘blinking’ while taking pictures and/or making a menu selection) from users and transforms the eye gestures as input into an input device (e.g., Google Glass®). Additionally, user interface input devices may include voice recognition sensing devices that enable users to interact with voice recognition systems (e.g., Siri® navigator), through voice commands.

User interface input devices may also include, without limitation, three dimensional (3D) mice, joysticks or pointing sticks, gamepads and graphic tablets, and audio/visual devices such as speakers, digital cameras, digital camcorders, portable media players, webcams, image scanners, fingerprint scanners, barcode reader 3D scanners, 3D printers, laser rangefinders, and eye gaze tracking devices. Additionally, user interface input devices may include, for example, medical imaging input devices such as computed tomography, magnetic resonance imaging, position emission tomography, medical ultrasonography devices. User interface input devices may also include, for example, audio input devices such as MIDI keyboards, digital musical instruments and the like.

User interface output devices may include a display subsystem, indicator lights, or non-visual displays such as audio output devices, etc. The display subsystem may be a cathode ray tube (CRT), a flat-panel device, such as that using a liquid crystal display (LCD) or plasma display, a projection device, a touch screen, and the like. In general, use of the term “output device” is intended to include all possible types of devices and mechanisms for outputting information from computer system 1100 to a user or other computer. For example, user interface output devices may include, without limitation, a variety of display devices that visually convey text, graphics and audio/video information such as monitors, printers, speakers, headphones, automotive navigation systems, plotters, voice output devices, and modems.

Computer system 1100 may comprise a storage subsystem 1118 that comprises software elements, shown as being currently located within a system memory 1110. System memory 1110 may store program instructions that are loadable and executable on processing unit 1104, as well as data generated during the execution of these programs.

Depending on the configuration and type of computer system 1100, system memory 1110 may be volatile (such as random access memory (RAM)) and/or non-volatile (such as read-only memory (ROM), flash memory, etc.) The RAM typically contains data and/or program modules that are immediately accessible to and/or presently being operated and executed by processing unit 1104. In some implementations, system memory 1110 may include multiple different types of memory, such as static random access memory (SRAM) or dynamic random access memory (DRAM). In some implementations, a basic input/output system (BIOS), containing the basic routines that help to transfer information between elements within computer system 1100, such as during start-up, may typically be stored in the ROM. By way of example, and not limitation, system memory 1110 also illustrates application programs 1112, which may include client applications, Web browsers, mid-tier applications, relational database management systems (RDBMS), etc., program data 1114, and an operating system 1116. By way of example, operating system 1116 may include various versions of Microsoft Windows®, Apple Macintosh®, and/or Linux operating systems, a variety of commercially-available UNIX® or UNIX-like operating systems (including without limitation the variety of GNU/Linux operating systems, the Google Chrome® OS, and the like) and/or mobile operating systems such as iOS, Windows® Phone, Android® OS, BlackBerry® 10 OS, and Palm® OS operating systems.

Storage subsystem 1118 may also provide a tangible computer-readable storage medium for storing the basic programming and data constructs that provide the functionality of some embodiments. Software (programs, code modules, instructions) that when executed by a processor provide the functionality described above may be stored in storage subsystem 1118. These software modules or instructions may be executed by processing unit 1104. Storage subsystem 1118 may also provide a repository for storing data used in accordance with some embodiments.

Storage subsystem 1100 may also include a computer-readable storage media reader 1120 that can further be connected to computer-readable storage media 1122. Together and, optionally, in combination with system memory 1110, computer-readable storage media 1122 may comprehensively represent remote, local, fixed, and/or removable storage devices plus storage media for temporarily and/or more permanently containing, storing, transmitting, and retrieving computer-readable information.

Computer-readable storage media 1122 containing code, or portions of code, can also include any appropriate media, including storage media and communication media, such as but not limited to, volatile and non-volatile, removable and non-removable media implemented in any method or technology for storage and/or transmission of information. This can include tangible computer-readable storage media such as RAM, ROM, electronically erasable programmable ROM (EEPROM), flash memory or other memory technology, CD-ROM, digital versatile disk (DVD), or other optical storage, magnetic cassettes, magnetic tape, magnetic disk storage or other magnetic storage devices, or other tangible computer readable media. This can also include nontangible computer-readable media, such as data signals, data transmissions, or any other medium which can be used to transmit the desired information and which can be accessed by computing system 1100.

By way of example, computer-readable storage media 1122 may include a hard disk drive that reads from or writes to non-removable, nonvolatile magnetic media, a magnetic disk drive that reads from or writes to a removable, nonvolatile magnetic disk, and an optical disk drive that reads from or writes to a removable, nonvolatile optical disk such as a CD ROM, DVD, and Blu-Ray® disk, or other optical media. Computer-readable storage media 1122 may include, but is not limited to, Zip® drives, flash memory cards, universal serial bus (USB) flash drives, secure digital (SD) cards, DVD disks, digital video tape, and the like. Computer-readable storage media 1122 may also include, solid-state drives (SSD) based on non-volatile memory such as flash-memory based SSDs, enterprise flash drives, solid state ROM, and the like, SSDs based on volatile memory such as solid state RAM, dynamic RAM, static RAM, DRAM-based SSDs, magnetoresistive RAM (MRAM) SSDs, and hybrid SSDs that use a combination of DRAM and flash memory based SSDs. The disk drives and their associated computer-readable media may provide non-volatile storage of computer-readable instructions, data structures, program modules, and other data for computer system 1100.

Communications subsystem 1124 provides an interface to other computer systems and networks. Communications subsystem 1124 serves as an interface for receiving data from and transmitting data to other systems from computer system 1100. For example, communications subsystem 1124 may enable computer system 1100 to connect to one or more devices via the Internet. In some embodiments communications subsystem 1124 can include radio frequency (RF) transceiver components for accessing wireless voice and/or data networks (e.g., using cellular telephone technology, advanced data network technology, such as 3G, 4G or EDGE (enhanced data rates for global evolution), WiFi (IEEE 802.11 family standards, or other mobile communication technologies, or any combination thereof), global positioning system (GPS) receiver components, and/or other components. In some embodiments communications subsystem 1124 can provide wired network connectivity (e.g., Ethernet) in addition to or instead of a wireless interface.

In some embodiments, communications subsystem 1124 may also receive input communication in the form of structured and/or unstructured data feeds 1126, event streams 1128, event updates 1130, and the like on behalf of one or more users who may use computer system 1100.

By way of example, communications subsystem 1124 may be configured to receive data feeds 1126 in real-time from users of social networks and/or other communication services such as Twitter® feeds, Facebook® updates, web feeds such as Rich Site Summary (RSS) feeds, and/or real-time updates from one or more third party information sources.

Additionally, communications subsystem 1124 may also be configured to receive data in the form of continuous data streams, which may include event streams 1128 of real-time events and/or event updates 1130, that may be continuous or unbounded in nature with no explicit end. Examples of applications that generate continuous data may include, for example, sensor data applications, financial tickers, network performance measuring tools (e.g. network monitoring and traffic management applications), clickstream analysis tools, automobile traffic monitoring, and the like.

Communications subsystem 1124 may also be configured to output the structured and/or unstructured data feeds 1126, event streams 1128, event updates 1130, and the like to one or more databases that may be in communication with one or more streaming data source computers coupled to computer system 1100.

Computer system 1100 can be one of various types, including a handheld portable device (e.g., an iPhone® cellular phone, an iPad® computing tablet, a PDA), a wearable device (e.g., a Google Glass® head mounted display), a PC, a workstation, a mainframe, a kiosk, a server rack, or any other data processing system.

Due to the ever-changing nature of computers and networks, the description of computer system 1100 depicted in the figure is intended only as a specific example. Many other configurations having more or fewer components than the system depicted in the figure are possible. For example, customized hardware might also be used and/or particular elements might be implemented in hardware, firmware, software (including applets), or a combination. Further, connection to other computing devices, such as network input/output devices, may be employed. Based on the disclosure and teachings provided herein, other ways and/or methods to implement the various embodiments should be apparent.

In the foregoing description, for the purposes of explanation, numerous specific details were set forth in order to provide a thorough understanding of various embodiments. It will be apparent, however, that some embodiments may be practiced without some of these specific details. In other instances, well-known structures and devices are shown in block diagram form.

The foregoing description provides exemplary embodiments only, and is not intended to limit the scope, applicability, or configuration of the disclosure. Rather, the foregoing description of various embodiments will provide an enabling disclosure for implementing at least one embodiment. It should be understood that various changes may be made in the function and arrangement of elements without departing from the spirit and scope of some embodiments as set forth in the appended claims.

Specific details are given in the foregoing description to provide a thorough understanding of the embodiments. However, it will be understood that the embodiments may be practiced without these specific details. For example, circuits, systems, networks, processes, and other components may have been shown as components in block diagram form in order not to obscure the embodiments in unnecessary detail. In other instances, well-known circuits, processes, algorithms, structures, and techniques may have been shown without unnecessary detail in order to avoid obscuring the embodiments.

Also, it is noted that individual embodiments may have been described as a process which is depicted as a flowchart, a flow diagram, a data flow diagram, a structure diagram, or a block diagram. Although a flowchart may have described the operations as a sequential process, many of the operations can be performed in parallel or concurrently. In addition, the order of the operations may be re-arranged. A process is terminated when its operations are completed, but could have additional steps not included in a figure. A process may correspond to a method, a function, a procedure, a subroutine, a subprogram, etc. When a process corresponds to a function, its termination can correspond to a return of the function to the calling function or the main function.

The term “computer-readable medium” includes, but is not limited to portable or fixed storage devices, optical storage devices, wireless channels and various other mediums capable of storing, containing, or carrying instruction(s) and/or data. A code segment or machine-executable instructions may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc., may be passed, forwarded, or transmitted via any suitable means including memory sharing, message passing, token passing, network transmission, etc.

Furthermore, embodiments may be implemented by hardware, software, firmware, middleware, microcode, hardware description languages, or any combination thereof. When implemented in software, firmware, middleware or microcode, the program code or code segments to perform the necessary tasks may be stored in a machine readable medium. A processor(s) may perform the necessary tasks.

In the foregoing specification, features are described with reference to specific embodiments thereof, but it should be recognized that not all embodiments are limited thereto. Various features and aspects of some embodiments may be used individually or jointly. Further, embodiments can be utilized in any number of environments and applications beyond those described herein without departing from the broader spirit and scope of the specification. The specification and drawings are, accordingly, to be regarded as illustrative rather than restrictive.

Additionally, for the purposes of illustration, methods were described in a particular order. It should be appreciated that in alternate embodiments, the methods may be performed in a different order than that described. It should also be appreciated that the methods described above may be performed by hardware components or may be embodied in sequences of machine-executable instructions, which may be used to cause a machine, such as a general-purpose or special-purpose processor or logic circuits programmed with the instructions to perform the methods. These machine-executable instructions may be stored on one or more machine readable mediums, such as CD-ROMs or other type of optical disks, floppy diskettes, ROMs, RAMs, EPROMs, EEPROMs, magnetic or optical cards, flash memory, or other types of machine-readable mediums suitable for storing electronic instructions. Alternatively, the methods may be performed by a combination of hardware and software.

What is claimed is:

1. A method of determining a thickness of a layer on a wafer during a chemical-mechanical polishing (CMP) process, the method comprising:
polishing the layer on the wafer using the CMP process;
monitoring the wafer during the CMP process with an in-situ spectrographic monitoring system to generate spectral data reflected from the wafer;
applying a bandpass filter operation to the spectral data to generate filtered spectral data, wherein the bandpass filter is configured to pass a frequency range corresponding to the layer on the wafer; and
matching the filtered spectral data to a reference filtered spectral data, wherein the reference filtered spectral data has been filtered using the bandpass filter operation, and the reference filtered spectral data is associated with a thickness of the layer.

2. The method of claim 1, further comprising:
generating a plurality of reference filtered spectral data by simulating a model corresponding to the wafer.

3. The method of claim 2, wherein matching the filtered spectral data to the reference filtered spectral data comprises:
calculating a similarity between the filtered spectral data and each of the plurality of reference filtered spectral data to identify the reference filtered spectral data as the most similar to the filtered spectral data.

4. The method of claim 2, wherein the model corresponding to the wafer comprises a simplified model that removes patterned features and/or layers below the layer on the wafer.

5. The method of claim 4, wherein the bandpass filter operation removes frequency components from spectral data that are associated with the patterned features and/or the layers below the layer on the wafer.

6. The method of claim 1, wherein the reference filtered spectral data is derived from spectral data measurements and thickness measurements from a setup wafer.

7. The method of claim 1, further comprising:
operating the CMP process based on the thickness of the layer until the layer on the wafer reaches a target thickness.

8. A system comprising:
a polishing pad;
a carrier head configured to hold a wafer against the polishing pad;
a monitoring system configured to direct light onto the wafer and receive light reflected from the wafer;
one or more processors; and
one or more memory devices comprising instructions that, when executed by the one or more processors, cause the one or more processors to perform operations comprising
receiving spectral data based on the light reflected from the wafer;
applying a bandpass filter operation to the spectral data to generate filtered spectral data, wherein the bandpass filter is configured to pass a frequency range corresponding to a layer on the wafer;
matching the filtered spectral data to a reference filtered spectral data, wherein the reference filtered spectral data has been filtered using the bandpass filter operation, and the reference filtered spectral data is associated with a thickness of the layer; and
controlling a polishing process of the wafer based on the thickness.

9. The system of claim 8, wherein the operations further comprise:
converting the spectral data into wavenumber space to generate wavenumber data representing a number of in-layer waves in the layer, wherein the wavenumber space depends on a wavelength-dependent refractive index of the layer for each data point in the spectral data.

10. The system of claim 9, wherein the operations further comprise:
interpolating the wavenumber data onto an evenly spaced distribution of wavenumber values.

11. The system of claim 10, wherein the evenly spaced distribution of wavenumber values comprises a power-of-2 number of wavenumber values.

12. The system of claim 10, wherein the operations further comprise:
calculating a Discrete Fourier Transformer (DFT) of the wavenumber data to generate DFT data.

13. The system of claim 12, wherein the operations further comprise:
identifying a window in the DFT data corresponding to an estimated thickness of the layer.

14. The system of claim 13, wherein applying the bandpass filter operation comprises setting values in the DFT data outside of the window to zero.

15. A non-transitory computer-readable medium comprising instructions that, when executed by one or more processors, cause the one or more processors to perform operations comprising:
receiving spectral data based on light reflected from a wafer;
applying a bandpass filter operation to the spectral data to generate filtered spectral data, wherein the bandpass filter is configured to pass a frequency range corresponding to a layer on the wafer;
matching the filtered spectral data to a reference filtered spectral data, wherein the reference filtered spectral data has been filtered using the bandpass filter operation, and the reference filtered spectral data is associated with a thickness of the layer; and
controlling a process performed on the wafer based on the thickness.

16. The non-transitory computer-readable medium of claim 15, wherein the spectral data comprises a plurality of peaks that are associated with layers other than the layer on the wafer.

17. The non-transitory computer-readable medium of claim 15, wherein applying the bandpass filter operation to the spectral data comprises:
identifying a frequency corresponding to a peak associated with the layer; and
applying the bandpass filter operation to the spectral data in a wavenumber domain or a wavelength domain, wherein the bandpass filter operation is centered on the frequency corresponding to the peak.

18. The non-transitory computer-readable medium of claim 15, applying the bandpass filter operation comprises:
converting the spectral data into wavenumber space to generate wavenumber data representing a number of in-layer waves in the layer, wherein the wavenumber space depends on a wavelength-dependent refractive index of the layer for each data point in the spectral data; and
interpolating the wavenumber data onto an evenly spaced distribution of wavenumber values.

19. The non-transitory computer-readable medium of claim 18, applying the bandpass filter operation further comprises:
calculating a Discrete Fourier Transformer (DFT) of the wavenumber data to generate DFT data;
identifying a window in the DFT data corresponding to an estimated thickness of the layer; and
setting values in the DFT data outside of the window to zero.

20. The non-transitory computer-readable medium of claim 19, applying the bandpass filter operation further comprises:
calculating an inverse DFT from the DFT data.
